(19) United States
(12) Patent Application Publication
(10) Pub. No.: US 2026/0020336 A1
(43) Pub. Date: Jan. 15, 2026

(54) SEMICONDUCTOR DEVICE

(71) Applicant: Samsung Electronics Co., Ltd., Suwon-si (KR)

(72) Inventors: Jin Myoung Lee, Suwon-si (KR); Jong Soo Baek, Suwon-si (KR)

(21) Appl. No.: 19/184,113

(22) Filed: Apr. 21, 2025

(30) Foreign Application Priority Data
Jul. 10, 2024 (KR) 10-2024-0091232

(51) Int. Cl. H10D 84/85; H01L 23/522; H01L 23/528; H02M 7/00; H10D 30/00; H10D 30/43; H10D 62/10; H10D 62/13; H10D 64/23

(52) U.S. Cl. CPC H10D 84/851; H01L 23/5226; H01L 23/5283; H02M 7/003; H10D 30/43; H10D 30/502; H10D 62/121; H10D 62/151; H10D 64/256; H10D 84/856

(57) ABSTRACT

There is provided a semiconductor device with improved integration and performance. The semiconductor device includes a substrate, a first lower active pattern, a first upper active pattern on the first lower active pattern, a first gate structure on the first lower active pattern and the first upper active pattern, a second lower active pattern spaced apart from the first lower active pattern, a second upper active pattern on the second lower active pattern and spaced apart from the first upper active pattern, a second gate structure on the second lower active pattern and the second upper active pattern, a first source/drain contact electrically connected to a first lower source/drain region of the first lower active pattern and a first upper source/drain region of the first upper active pattern and a first back connecting wire and electrically connecting the first source/drain contact and the second gate structure.

### CROSS-REFERENCE TO RELATED APPLICATION

This application claims priority from Korean Patent Application No. 10-2024-0091232 filed on Jul. 10, 2024 in the Korean Intellectual Property Office, and all the benefits accruing therefrom under 35 U.S.C. 119, the contents of which in its entirety are herein incorporated by reference.

### BACKGROUND

The present disclosure relates to a semiconductor device, and more particularly, to a semiconductor device including a stacked multi-gate transistor.

As one of the scaling technologies to increase the density of integrated circuit (IC) devices, multi-gate transistors have been proposed in which a fin-shaped or nanowire-shaped silicon body is formed on a substrate and then gates are formed on the surface of the silicon body.

Since these multi-gate transistors utilize three-dimensional (3D) channels, scaling is easier. Moreover, current control capabilities can be enhanced without increasing the gate length of the multi-gate transistors. Additionally, a short channel effect (SCE), where the potential of a channel region is influenced by a drain voltage, can be effectively suppressed.

To implement more devices in the same area, research is being conducted on semiconductor devices that use stacked multi-gate transistors, where multi-gate transistors in the upper region are stacked on multi-gate transistors in the lower region.

### SUMMARY

Embodiments of the present disclosure provide a semiconductor device with improved integration and performance.

However, embodiments of the present disclosure are not restricted to those set forth herein. The above and other embodiments of the present disclosure will become more apparent to one of ordinary skill in the art to which the present disclosure pertains by referencing the detailed description of the present disclosure given below

According to some embodiments of the present disclosure, there is provided a semiconductor device comprising a substrate including first and second surfaces that are opposite to each other, a first lower active pattern extending in a first direction on the first surface of the substrate, a first upper active pattern on the first lower active pattern and extending in the first direction, a first gate structure, extending in a second direction which intersects the first direction, on the first lower active pattern and on the first upper active pattern, a second lower active pattern extending in the first direction on the substrate and spaced apart from the first lower active pattern in the first direction, a second upper active pattern on the second lower active pattern, extending in the first direction, and spaced apart from the first upper active pattern in the first direction, a second gate structure extending in the second direction on the second lower active pattern and on the second upper active pattern, a first source/drain contact electrically connected to a first lower source/drain region of the first lower active pattern, a first upper source/drain region of the first upper active pattern on the first source/drain contact, and a first back connecting wire extending in the first direction and electrically connecting the first source/drain contact and the second gate structure.

According to some embodiments of the present disclosure, there is provided a semiconductor device comprising a substrate including a first surface and a second surface that are opposite to each other, a plurality of cell regions electrically connected in series on the substrate, each of the cell regions comprising an inverter circuit, a front wiring structure on the first surface of the substrate and a back wiring structure on the second surface of the substrate, wherein the cell regions include first and second cell regions that are alternately arranged, the first cell region includes: a first lower active pattern on the first surface of the substrate and extending in a first direction; a first upper active pattern on the first lower active pattern and extending in the first direction; a first gate structure extending in a second direction intersecting the first direction on the first lower active pattern and on the first upper active pattern; and a first source/drain contact electrically connected to a first lower source/drain region of the first lower active pattern and a first upper source/drain region of the first upper active pattern, the second cell region includes: a second lower active pattern on the first surface of the substrate and extending in the first direction; a second upper active pattern on the second lower active pattern and extending in the first direction; a second gate structure extending in the second direction on the second lower active pattern and the second upper active pattern; and a second source/drain contact electrically connected to a second lower source/drain region of the second lower active pattern and a second upper source/drain region of the second upper active pattern, the first gate structure and the second source/drain contact are electrically connected to the front wiring structure, and the first source/drain contact and the second gate structure are electrically connected to the back wiring structure.

According to some embodiments of the present disclosure, there is provided a semiconductor device comprising a substrate including a first surface and a second surface that are opposite to each other, an odd number of cell regions electrically connected in series on the substrate to form a closed-loop circuit, each of the cell regions including an inverter circuit and a back connecting wire on the second surface of the substrate. Each of the cell regions includes a lower active pattern on the first surface of the substrate; an upper active pattern on the lower active pattern; a gate structure intersecting the lower active pattern and the upper active pattern; and a source/drain contact electrically connected to a lower source/drain region of the lower active pattern and an upper source/drain region of the upper active pattern, and the back connecting wire is electrically connected to the source/drain contact or a gate electrode of at least one of the cell regions.

It should be noted that the effects of the present disclosure are not limited to those described above, and other effects of the present disclosure will be apparent from the following description.

### BRIEF DESCRIPTION OF THE DRAWINGS

The above and other embodiments and features of the present disclosure will become more apparent by describing in detail example embodiments thereof with reference to the attached drawings, in which:

FIG. 1 is an example circuit diagram for explaining a semiconductor device according to some embodiments.

FIG. 2 is a circuit diagram for explaining an inverter circuit of FIG. 1.

FIG. 3 is an example layout view for explaining the semiconductor device according to some embodiments.

FIG. 4 is a schematic cross-sectional view taken along line A-A of FIG. 3.

FIG. 5 is a schematic cross-sectional view taken along line B-B of FIG. 3.

FIG. 6 is a schematic cross-sectional view taken along line C-C of FIG. 3.

FIG. 7 is a schematic cross-sectional view taken along line D-D of FIG. 3.

FIG. 8 is a schematic cross-sectional view taken along line E-E of FIG. 3.

FIG. 9 is a schematic cross-sectional view taken along line F-F of FIG. 3.

FIG. 10 is an example layout view for explaining a semiconductor device according to some embodiments.

FIG. 11 is a schematic cross-sectional view taken along line G-G of FIG. 10.

FIG. 12 is an example layout view for explaining a semiconductor device according to some embodiments.

FIG. 13 is a schematic cross-sectional view taken along line H-H of FIG. 12.

FIG. 14 is an example layout view for explaining a semiconductor device according to some embodiments.

FIG. 15 is a schematic cross-sectional view taken along line I-I of FIG. 14.

FIG. 16 is an example layout view for explaining a semiconductor device according to some embodiments.

FIG. 17 is a schematic cross-sectional view taken along line J-J of FIG. 16.

FIG. 18 is an example layout view for explaining a semiconductor device according to some embodiments.

FIG. 19 is a schematic cross-sectional view taken along line K-K of FIG. 18.

FIG. 20 is an example layout view for explaining a semiconductor device according to some embodiments.

FIG. 21 is a schematic cross-sectional view taken along line L-L of FIG. 20.

FIG. 22 is an example circuit diagram for explaining a semiconductor device according to some embodiments.

### DETAILED DESCRIPTION

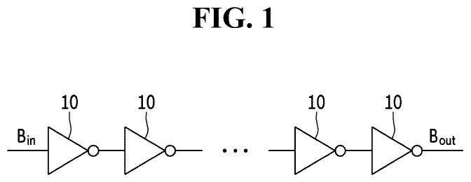

Embodiments of the present disclosure will be described with reference to FIGS. 1 through 22.

In this specification, terms such as “first,” “second,” etc., are used to describe various devices or elements, but these devices or elements are not limited by these terms. These terms are only used to distinguish one device or element from another. Therefore, a first device or element mentioned below may be a second device or element within the technical scope of the present disclosure.

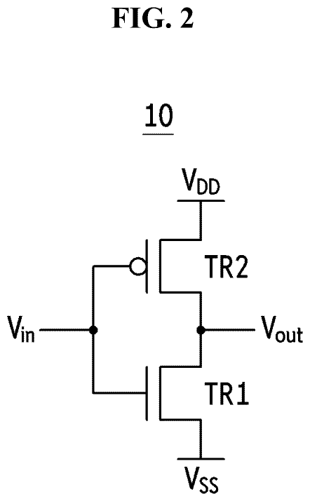

FIG. 1 is an example circuit diagram for explaining a semiconductor device according to some embodiments. FIG. 2 is a circuit diagram for explaining an inverter circuit of FIG. 1.

Referring to FIGS. 1 and 2, the semiconductor device according to some embodiments includes a plurality of inverter circuits 10 that are connected in series.

Each of the inverter circuits 10 may be a complementary metal-oxide semiconductor (CMOS) inverter. For example, as illustrated in FIG. 2, each of the inverter circuits 10 may include a first transistor TR1 and a second transistor TR2 that are connected in series between a first power node V_{SS} and a second power node V_{DD}. The first transistor TR1 may be an N-channel field-effect transistor (NFET), and the second transistor TR2 may be a P-channel field-effect transistor (PFET). The source of the first transistor TR1 may be connected to the first power node V_{SS}, and the source of the second transistor TR2 may be connected to the second power node V_{DD}. An input signal Vᵢₙ of each of the inverter circuits 10 may be input to the gate of the first transistor TR1 and the gate of the second transistor TR2. An output signal Vₒᵤₜ of each of the inverter circuits 10 may be output from the node where the drain of the first transistor TR1 and the drain of the second transistor TR2 are connected.

A plurality of inverter circuits 10 may be connected in series. For example, an output signal Vₒᵤₜ of one inverter circuit 10 may be provided as an input signal Vᵢₙ to a neighboring inverter circuit 10.

In some embodiments, an even number of inverter circuits 10 electrically connected in series may be provided. These even number of inverter circuits 10 may be provided as timing buffer circuits that transmit an input signal Bᵢₙ as an output signal Bₒᵤₜ without changing it.

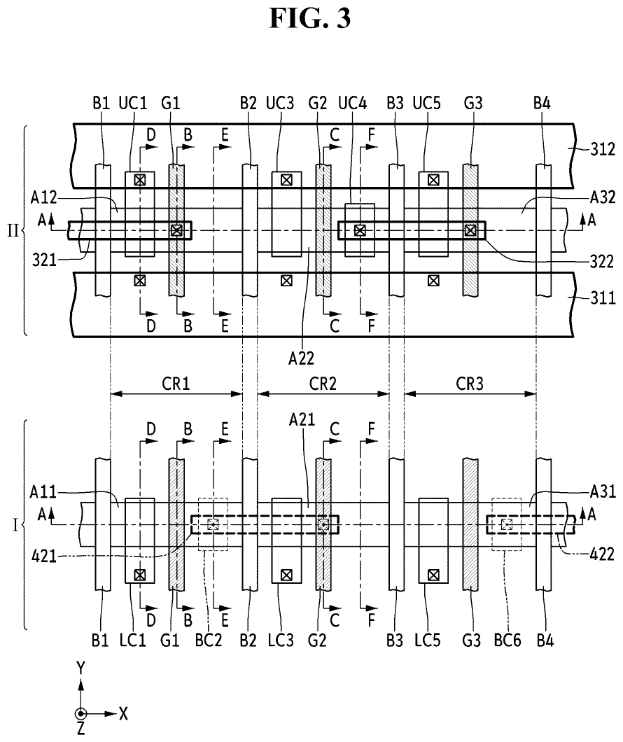

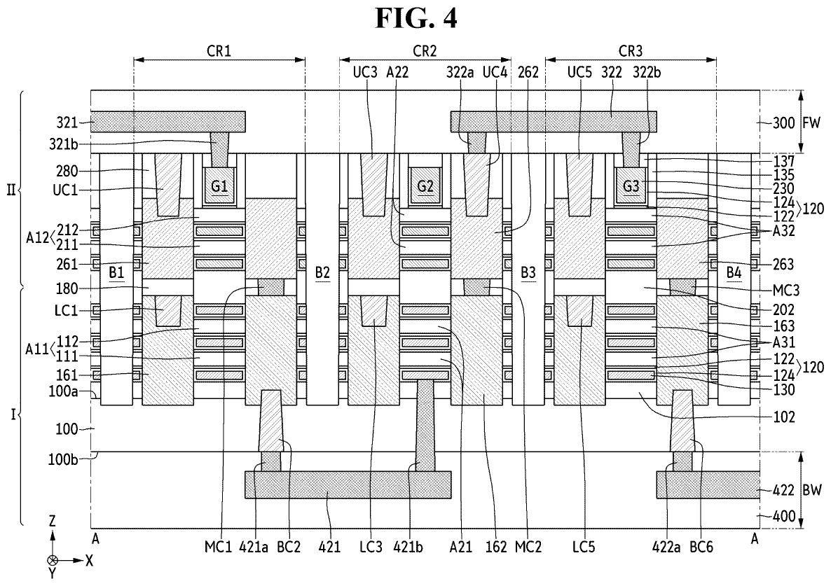

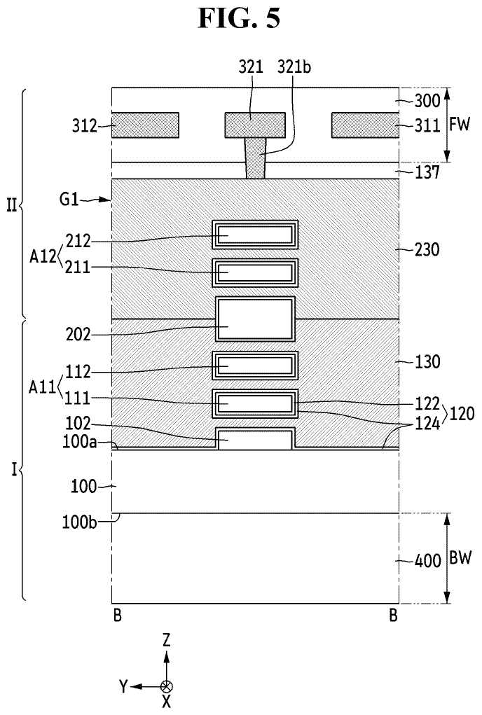

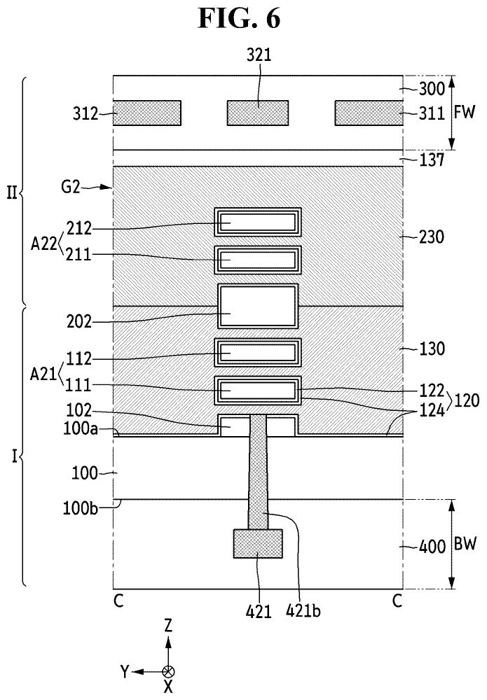

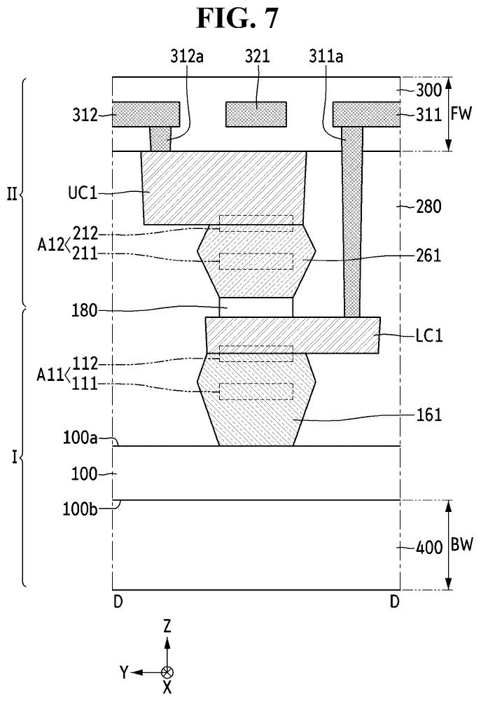

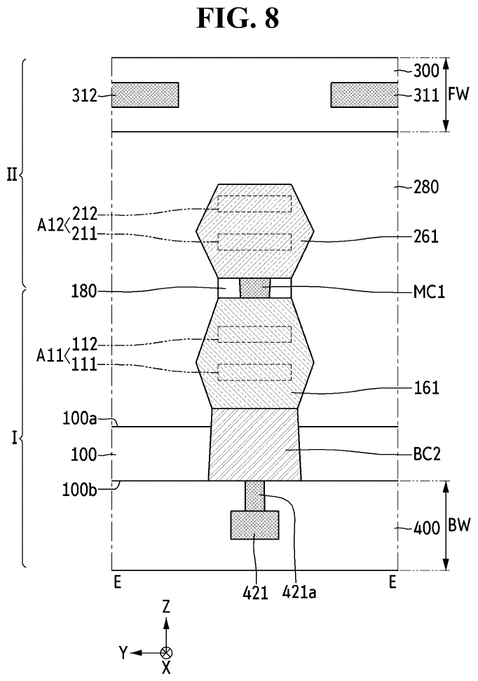

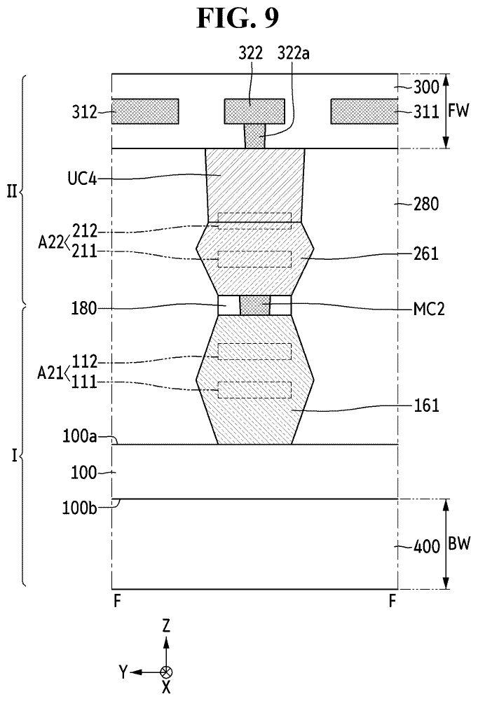

FIG. 3 is an example layout view for explaining the semiconductor device according to some embodiments. FIG. 4 is a schematic cross-sectional view taken along line A-A of FIG. 3. FIG. 5 is a schematic cross-sectional view taken along line B-B of FIG. 3. FIG. 6 is a schematic cross-sectional view taken along line C-C of FIG. 3. FIG. 7 is a schematic cross-sectional view taken along line D-D of FIG. 3. FIG. 8 is a schematic cross-sectional view taken along line E-E of FIG. 3. FIG. 9 is a schematic cross-sectional view taken along line F-F of FIG. 3.

Referring to FIGS. 1 through 9, the semiconductor device according to some embodiments may include a first region I and a second region II.

The first and second regions I and II may be sequentially stacked along a third direction Z. Different types of transistors may be formed in the first and second regions I and II. The first region I may be, but is not limited to, an NFET region, and the second region II may be, but is not limited to, a PFET region. In some embodiments, the first region I may be a PFET region, and the second region II may be an NFET region.

The semiconductor device according to some embodiments may include a first cell region CR1, a second cell region CR2, and a third cell region CR3 that are adjacent to one another.

For example, the first, second, and third cell regions CR1, CR2, and CR3 may be arranged sequentially along a first direction X. The second cell region CR2 may be interposed between the first cell region CR1 and the third cell region CR3 in the first direction X.

Each of the first, second, and third cell regions CR1, CR2, and CR3 may provide the inverter circuits 10 of FIGS. 1 and 2 on a substrate 100. The first, second, and third cell regions CR1, CR2, and CR3 may be connected in series. For example, the output signal of the first cell region CR1 may be provided as an input signal to the second cell region CR2, and the output signal of the second cell region CR2 may be provided as an input signal to the third cell region CR3.

The semiconductor device according to some embodiments may include the substrate 100; a first lower active pattern A11, a second lower active pattern A21, and a third lower active pattern A31; a first upper active pattern A12, a second upper active pattern A22, and a third upper active pattern A32; a first gate structure G1, a second gate structure G2, and a third gate structure G3; a first isolation structure B1, a second isolation structure B2, a third isolation structure B3, and a fourth isolation structure B4; first lower source/drain regions 161, second lower source/drain regions 162, and third lower source/drain regions 163; first upper source/drain regions 261, second upper source/drain regions 262, and third upper source/drain regions 263; source/drain contacts (LCp, UCq, and BCr) (where p, q, and r are natural numbers); a front wiring structure FW; and a back wiring structure BW.

The substrate 100 may include bulk silicon or silicon-on-insulator (SOI). In some embodiments, the substrate 100 may be a silicon substrate or include another material, for example, silicon-germanium (SiGe), SiGe-on-insulator (SGOI), indium antimonide, a lead telluride compound, indium arsenide, indium phosphide, gallium arsenide, or gallium antimonide. In some embodiments, the substrate 100 may be an epitaxial layer formed on a base substrate.

In some embodiments, the substrate 100 may be an insulating substrate including an insulating material. For example, the substrate 100 may include at least one of silicon oxide, silicon oxynitride, silicon nitride, or a combination thereof, but the present disclosure is not limited thereto. For example, the substrate 100 may include a silicon oxide film.

The substrate 100 may include a first surface 100a and a second surface 100b that are opposite to each other. The first surface 100a may also be referred to as the front side of the substrate 100, and the second surface 100b may also be referred to as the back side of the substrate 100.

First, second, and third lower active patterns A11, A21, and A31 may be formed on the first surface 100a of the substrate 100. The first, second, and third lower active patterns A11, A21, and A31 may be spaced apart from the substrate 100 and extend in the first direction X. The first, second, and third lower active patterns A11, A21, and A31 may be sequentially arranged along the first direction X.

A first upper active pattern A12, a second upper active pattern A22, and a third upper active pattern A32 may be formed on the first lower active pattern A11, the second lower active pattern A21, and the third lower active pattern A31, respectively. The first, second, and third upper active patterns A12, A22, and A32 may be spaced apart from the first, second, and third lower active patterns A11, A12, and A31, respectively, and extend in the first direction X. The first, second, and third upper active patterns A12, A22, and A32 may be sequentially arranged along the first direction X.

The first lower active pattern A11 and the first upper active pattern A12 may be sequentially stacked on the first surface 100a of the first cell region CR1. The first lower active pattern A11 and the first upper active pattern A12 may be spaced apart from each other in the third direction Z and extend in the first direction X.

The second lower active pattern A21 and the second upper active pattern A22 may be sequentially stacked on the first surface 100a of the second cell region CR2. The second lower active pattern A21 and the second upper active pattern A22 may be spaced apart from each other in the third direction Z and extend in the first direction X. The second lower active pattern A21 may be spaced apart from the first lower active pattern A11 in the first direction X. The second upper active pattern A22 may be spaced apart from the first upper active pattern A12 in the first direction X.

The third lower active pattern A31 and the third upper active pattern A32 may be sequentially stacked on the first surface 100a of the third cell region CR3. The third lower active pattern A31 and the third upper active pattern A32 may be spaced apart from each other in the third direction Z and extend in the first direction X. The third lower active pattern A31 may be spaced apart from the second lower active pattern A21 in the first direction X. The third upper active pattern A32 may be spaced apart from the second upper active pattern A22 in the first direction X.

In some embodiments, each of the first, second, and third lower active patterns A11, A21, and A31 may include a plurality of lower bridge patterns (111 and 112) that are sequentially stacked on the substrate 100 and spaced apart from one another. In some embodiments, each of the first, second, and third upper active patterns A12, A22, and A32 may include a plurality of upper bridge patterns (211 and 212) that are sequentially stacked on the first, second, and third lower active patterns A11, A21, and A31 and are spaced apart from one another. The lower bridge patterns (111 and 112) and the upper bridge patterns (211 and 212) may be used as the channel regions of Multi-Bridge-Channel Field-Effect Transistors (MBCFETs®), which include multi-bridge channels. The number of lower bridge patterns (111 and 112) and the number of upper bridge patterns (211 and 212) are merely example and are not particularly limited.

The first, second, and third lower active patterns A11, A21, and A31 and the first, second, and third upper active patterns A12, A22, and A32 may each include an elemental semiconductor material such as silicon (Si) or germanium (Ge). In some embodiments, the first, second, and third lower active patterns A11, A21, and A31 and the first, second, and third upper active patterns A12, A22, and A32 may each include a compound semiconductor, for example, a Group IV-IV compound semiconductor or a Group III-V compound semiconductor. The Group IV-IV compound semiconductor may include, for example, a binary or ternary compound including at least two of carbon (C), Si, Ge, and/or tin (Sn), or a compound obtained by doping the binary or ternary compound with a Group IV element. The Group III-V compound semiconductor may include, for example, a binary, ternary, or quaternary compound obtained by combining at least one Group III element such as aluminum (Al), gallium (Ga), or indium (In) with at least one Group V element such as phosphorus (P), arsenic (As), and/or antimony (Sb).

When the first region I is an NFET region and the second region II is a PFET region, the first, second, and third lower active patterns A11, A21, and A31 may be provided as the channel regions of the first transistor TR1 in FIG. 2, and the first, second, and third upper active patterns A12, A22, and A32 may be provided as the channel regions of the second transistor TR2 in FIG. 2.

In some embodiments, a base insulating pattern 102 may be formed between the substrate 100 and the first, second, and third lower active patterns A11, A21, and A31. The base insulating pattern 102 may extend in the first direction X. The base insulating pattern 102 may electrically isolate the substrate 100 from the first, second, and third lower active patterns A11, A21, and A31. The base insulating pattern 102 may include, for example, at least one of silicon oxide, silicon oxynitride, silicon oxycarbonitride, and/or a combination thereof, but the present disclosure is not limited thereto. For example, the base insulating pattern 102 may include a silicon nitride film.

In some embodiments, an intermediate insulating pattern 202 may be formed between the first, second, and third lower active patterns A11, A21, and A31 and the first, second, and third upper active patterns A12, A22, and A32. The intermediate insulating pattern 202 may extend in the first direction X. The intermediate insulating pattern 202 may electrically isolate the first, second, and third lower active patterns A11, A21, and A31 from the first, second, and third upper active patterns A12, A22, and A32. The intermediate insulating pattern 202 may include, for example, at least one of silicon oxide, silicon oxynitride, silicon oxynitride, and/or a combination thereof, but the present disclosure is not limited thereto. For example, the intermediate insulating pattern 202 may include a silicon nitride film.

The first, second, and third gate structures G1, G2, and G3 may be formed on the first, second, and third lower active patterns A11, A21, and A31 and the first, second, and third upper active patterns A12, A22, and A32. The first, second, and third gate structures G1, G2, and G3 may each extend in the second direction Y.

The first gate structure G1 may intersect the first lower active pattern A11 and the first upper active pattern A12. The second gate structure G2 may intersect the second lower active pattern A21 and the second upper active pattern A22. The third gate structure G3 may intersect the third lower active pattern A31 and the third upper active pattern A32.

In some embodiments, the first, second, and third gate structures G1, G2, and G3 may surround the peripheries of the first, second, and third lower active patterns A11, A21, and A31 and the peripheries of the first, second, and third upper active patterns A12, A22, and A32. For example, the bridge patterns (111, 112, 211, and 212) may each extend in the first direction X and penetrate or extend into the first, second, and third gate structures G1, G2, and G3.

Each of the first, second, and third gate structures G1, G2, and G3 may include a gate dielectric film 120, a lower gate electrode 130, an upper gate electrode 230, gate spacers 135, and a gate capping film 137.

The gate dielectric film 120 may be interposed between the first, second, and third lower active patterns A11, A21, and A31 and the lower gate electrode 130, and between the first, second, and third upper active patterns A12, A22, and A32 and the upper gate electrode 230. The gate dielectric film 120 may include, for example, at least one of silicon oxide, silicon oxynitride, silicon nitride, and/or a high-k dielectric material with a higher dielectric constant than silicon oxide. The high-k dielectric material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanate, barium titanate, strontium titanate, yttrium oxide, aluminum oxide, lead scandium tantalate, lead zinc niobate, and/or a combination thereof, but the present disclosure is not limited thereto.

In some embodiments, the gate dielectric film 120 may include an interfacial film 122 and a high-k dielectric film 124 that are sequentially stacked on each of the bridge patterns (111, 112, 211, and 212).

The interfacial film 122 may surround each of the bridge patterns (111, 112, 211, and 212). For example, the interfacial film 122 may conformally extend along each of the bridge patterns (111, 112, 211, and 212). In some embodiments, the interfacial film 122 may include an oxide film formed by oxidizing the surfaces of the bridge patterns (111, 112, 211, and 212). For example, when each of the bridge patterns (111, 112, 211, and 212) includes Si, the interfacial film 122 may include a silicon oxide film.

The high-k dielectric film 124 may surround the interfacial film 122. Additionally, part of the high-k dielectric film 124 may be interposed between the upper gate electrode 230 and gate spacers 135. For example, the high-k dielectric film 124 may conformally extend along the interfacial film 122 and the inner profile of the gate spacers 135. The high-k dielectric film 124 may further extend along the substrate 100, the base insulating pattern 102, and the intermediate insulating pattern 202.

In some embodiments, the high-k dielectric film 124 may include a high-k dielectric material with a higher dielectric constant than silicon oxide. The high-k dielectric material may include hafnium oxide (HfO₂), zirconium oxide (ZrO₂), lanthanum oxide (La₂O₃), aluminum oxide (Al₂O₃), titanium oxide (TiO₂), strontium titanate (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}), and/or a combination thereof, but the present disclosure is not limited thereto.

The lower gate electrode 130 may be disposed in the first region I. The lower gate electrode 130 may intersect the first, second, and third lower active patterns A11, A21, and A31. For example, the lower bridge patterns (111 and 112) may each extend in the first direction X and penetrate or extend into the lower gate electrode 130.

The upper gate electrode 230 may be disposed in the second region II. The upper gate electrode 230 may intersect the first, second, and third upper active patterns A12, A22, and A32. For example, the upper bridge patterns (211 and 212) may each extend in the first direction X and penetrate or extend into the upper gate electrode 230.

The upper gate electrode 230 may be electrically connected to the lower gate electrode 130. For example, the upper gate electrode 230 may be in direct contact with the top surface of the lower gate electrode 130.

The lower gate electrode 130 and the upper gate electrode 230 may each include a conductive material, for example, at least one of TiN, WN, TaN, Ru, TiC, TaC, Ti, Ag, Al, TiAl, TiAlN, TiAlC, TaCN, TaSiN, Mn, Zr, W, Al, and/or a combination thereof, but the present disclosure is not limited thereto. The lower gate electrode 130 and the upper gate electrode 230 may each be formed by a replacement process, but the present disclosure is not limited thereto.

The lower gate electrode 130 and the upper gate electrode 230 are illustrated as being single films, but the present disclosure is not limited thereto. In some embodiments, each of the lower gate electrode 130 and the upper gate electrode 230 may be formed by stacking a plurality of conductive films. For example, the lower gate electrode 130 and the upper gate electrode 230 may each include a work function control film and a filling conductive film that partially or completely fills the space formed by the work function control layer. The work function control film may include, for example, at least one of TiN, TaN, TiC, TaC, TiAlC, and/or a combination thereof. The filling conductive film may include, for example, W or Al.

In some embodiments, the lower gate electrode 130 and the upper gate electrode 230 may include different conductive materials. For example, the lower gate electrode 130 and the upper gate electrode 230 may include work function control films of different conductivity types. For example, the lower gate electrode 130 may include an n-type work function control film, and the upper gate electrode 230 may include a p-type work function control film.

When the first region I is an NFET region and the second region II is a PFET region, the lower gate electrode 130 may be provided as the gate of the first transistor TR1 of FIG. 2, and the upper gate electrode 230 may be provided as the gate of the second transistor TR2 of FIG. 2.

The gate spacers 135 may extend along the sides of the lower gate electrode 130 and the upper gate electrode 230. The bridge patterns (111, 112, 211, and 212) may each extend in the first direction X and penetrate or extend into the gate spacers 135. The gate spacers 135 may include an insulating material, for example, at least one of silicon oxide, silicon nitride, silicon oxynitride, silicon oxycarbide, silicon boron nitride, silicon carbonitride, silicon oxynitride carbide, and/or a combination thereof, but the present disclosure is not limited thereto.

The gate capping film 137 may extend along the top surface of the upper gate electrode 230. The gate capping film 137 may include an insulating material, for example, at least one of silicon oxide, silicon nitride, silicon oxynitride, silicon oxycarbide, silicon boron nitride, silicon carbonitride, silicon oxynitride carbide, and/or a combination thereof, but the present disclosure is not limited thereto.

The first, second, third, and fourth isolation structures B1, B2, B3, and B4 may each extend in the second direction Y. The first, second, third, and fourth isolation structures B1, B2, B3, and B4 may be sequentially arranged along the first direction X. The first, second, third, and fourth isolation structures B1, B2, B3, and B4 may separate the first, second, and third lower active patterns A11, A21, and A31 from one another and the first, second, and third upper active patterns A12, A22, and A32 from one another.

The first gate structure G1 may be interposed between the first and second isolation structures B1 and B2. The second gate structure G2 may be interposed between the second and third isolation structures B2 and B3. The third gate structure G3 may be interposed between the third and fourth isolation structures B3 and B4. The second isolation structure B2 may separate the first lower active pattern A11 from the second lower active pattern A21 and the first upper active pattern A12 from the second upper active pattern A22. The third isolation structure B3 may separate the second lower active pattern A21 from the third lower active pattern A31 and the second upper active pattern A22 from the third upper active pattern A32.

The first and second isolation structures B1 and B2 may define the first cell region CR1 in the first direction X. The second and third isolation structures B2 and B3 may define the second cell region CR2 in the first direction X. The third and fourth isolation structures B3 and B4 may define the third cell region CR3 in the first direction X.

The first, second, third, and fourth isolation structures B1, B2, B3, and B4 may each include an insulating material, for example, at least one of silicon oxide, silicon nitride, silicon oxynitride, silicon oxycarbide, silicon boron nitride, silicon carbonitride, silicon oxynitride carbide, and/or a combination thereof, but the present disclosure is not limited thereto. For example, the first, second, third, and fourth isolation structures B1, B2, B3, and B4 may each include a silicon oxide film.

The first lower source/drain regions 161, the second lower source/drain regions 162, and the third lower source/drain regions 163 may be formed in the first lower active pattern A11, the second lower active pattern A21, and the third lower active pattern A31, respectively, on the sides of the first, second, and third gate structures G1, G2, and G3 and on the sides of the first, second, third, and fourth isolation structures B1, B2, B3, and B4. The lower bridge patterns (111 and 112) may penetrate or extend into the lower gate electrode 130 and the gate spacers 135 and may be connected to the first lower source/drain regions 161, the second lower source/drain regions 162, and the third lower source/drain regions 163. The first lower source/drain regions 161, the second lower source/drain regions 162, and the third lower source/drain regions 163 may be separated from the lower gate electrode 130 by the gate spacers 135 and/or the gate dielectric film 120. The first lower source/drain regions 161, the second lower source/drain regions 162, and the third lower source/drain regions 163 may be described as components included in the first, second, and third lower active patterns A11, A21, and A31, or as separate components distinct from the first, second, and third lower active patterns A11, A21, and A31.

In some embodiments, the first lower source/drain regions 161, the second lower source/drain regions 162, and the third lower source/drain regions 163 may include epitaxial layers doped with impurities. For example, the first lower source/drain regions 161, the second lower source/drain regions 162, and the third lower source/drain regions 163 may include epitaxial patterns grown from the first lower active pattern A11, the second lower active pattern A21, and the third lower active pattern A31, respectively, by an epitaxial growth method. When the first region I is an NFET region, the first lower source/drain regions 161, the second lower source/drain regions 162, and the third lower source/drain regions 163 may each include n-type impurities (e.g., P, Sb, or As) and/or impurities to prevent the diffusion of the n-type impurities.

The first upper source/drain regions 261, the second upper source/drain regions 262, and the third upper source/drain regions 263 may be formed in the first upper active pattern A12, the second upper active pattern A22, and the third upper active pattern A32, respectively, on the sides of the first, second, and third gate structures G1, G2, and G3 and the sides of the first, second, third, and fourth isolation structures B1, B2, B3, and B4. The upper bridge patterns (211 and 212) may penetrate or extend into the upper gate electrode 230 and the gate spacers 135 and be connected to the first upper source/drain regions 261, the second upper source/drain regions 262, and the third upper source/drain regions 263, respectively. The first upper source/drain regions 261, the second upper source/drain regions 262, and the third upper source/drain regions 263 may be separated from the upper gate electrode 230 by the gate spacers 135 and/or the gate dielectric film 120. In this specification, the first upper source/drain regions 261, the second upper source/drain regions 262, and the third upper source/drain regions 263 may be described as components included in the first upper active pattern A12, the second upper active pattern A22, and the third upper active pattern A32, respectively, or as separate components distinct from the first upper active pattern A12, the second upper active pattern A22, and the third upper active pattern A32.

In some embodiments, the first upper source/drain regions 261, the second upper source/drain regions 262, and the third upper source/drain regions 263 may each include epitaxial layers doped with impurities. For example, the first upper source/drain regions 261, the second upper source/drain regions 262, and the third upper source/drain regions 263 may include epitaxial patterns grown from the first upper active pattern A12, the second upper active pattern A22, and the third upper active pattern A32, respectively, by an epitaxial growth method. When the second region II is a PFET region, the first upper source/drain regions 261, the second upper source/drain regions 262, and the third upper source/drain regions 263 may each include p-type impurities (e.g., B, In, Ga, or Al) and/or impurities to prevent the diffusion of the p-type impurities.

In some embodiments, an intermediate insulating layer 180 may be formed between the first lower source/drain regions 161, the second lower source/drain regions 162, and the third lower source/drain regions 163 and the first upper source/drain regions 261, the second upper source/drain regions 262, and the third upper source/drain regions 263, respectively. The intermediate insulating layer 180 may electrically isolate the first lower source/drain regions 161, the second lower source/drain regions 162, and the third lower source/drain regions 163 from the first upper source/drain regions 261, the second upper source/drain regions 262, and the third upper source/drain regions 263, respectively. The intermediate insulating layer 180 may include, for example, at least one of silicon oxide, silicon oxynitride, silicon oxynitride carbide, and/or a combination thereof, but the present disclosure is not limited thereto.

An interlayer insulating film 280 may partially or completely fill the spaces on the outer surfaces of the gate spacers 135, the outer surfaces of the first lower source/drain regions 161, the second lower source/drain regions 162, and the third lower source/drain regions 163, and the outer surfaces of the first upper source/drain regions 261, the second upper source/drain regions 262, and the third upper source/drain regions 263. The interlayer insulating film 280 may include, for example, at least one of silicon oxide, silicon nitride, silicon oxynitride, silicon oxycarbide, silicon boron nitride, silicon carbonitride, silicon oxynitride carbide, and/or a low-k dielectric material with a lower dielectric constant than silicon oxide, but the present disclosure is not limited thereto.

The source/drain contacts (LCp, UCq, and BCr) (where p, q, and r are natural numbers) may be connected to the first lower source/drain regions 161, the second lower source/drain regions 162, and the third lower source/drain regions 163 and/or the first upper source/drain regions 261, the second upper source/drain regions 262, and the third upper source/drain regions 263. In FIGS. 3 through 9, the number, shape, and arrangement of the source/drain contacts (LCp, UCq, and BCr) are merely example and are not particularly limited.

In some embodiments, the source/drain contacts (LCp, UCq, and BCr) may include lower source/drain contacts LCp (where p is a natural number), upper source/drain contacts UCq (where q is a natural number), and backside source/drain contacts BCr (where r is a natural number).

The lower source/drain contacts LCp may be connected to the first lower source/drain regions 161, the second lower source/drain regions 162, and the third lower source/drain regions 163. The lower source/drain contacts LCp may be formed on the first surface 100a of the substrate 100. For example, as illustrated, the lower source/drain contacts LCp may be connected to the tops of the first lower source/drain regions 161, the second lower source/drain regions 162, and the third lower source/drain regions 163 below the intermediate insulating layer 180.

For example, the lower source/drain contacts LCp may include a first lower source/drain contact LC1, a third lower source/drain contact LC3, and a fifth lower source/drain contact LC5. The first lower source/drain contact LC1 may be connected to the first lower source/drain region 161 between the first isolation structure B1 and the first gate structure G1. The third lower source/drain contact LC3 may be connected to the second lower source/drain region 162 between the second isolation structure B2 and the second gate structure G2. The fifth lower source/drain contact LC5 may be connected to the third lower source/drain region 163 between the third isolation structure B3 and the third gate structure G3.

The upper source/drain contacts UCq may be electrically connected to the first upper source/drain regions 261, the second upper source/drain regions 262, and the third upper source/drain regions 263. The upper source/drain contacts UCq may be formed on the first surface 100a of the substrate 100. For example, as illustrated, the upper source/drain contacts UCq may penetrate or extend into the interlayer insulating film 280 and may be connected to or be on the tops of the first upper source/drain regions 261, the second upper source/drain regions 262, and the third upper source/drain regions 263.

For example, the upper source/drain contacts UCq may include a first upper source/drain contact UC1, a third upper source/drain contact UC3, a fourth upper source/drain contact UC4, and a fifth upper source/drain contact UC5. The first upper source/drain contact UC1 may be electrically connected to the first upper source/drain region 261 between the first isolation structure B1 and the first gate structure G1. The third upper source/drain contact UC3 may be electrically connected to the second upper source/drain region 262 between the second isolation structure B2 and the second gate structure G2. The fourth upper source/drain contact UC4 may be electrically connected to the second upper source/drain region 262 between the second gate structure G2 and the third isolation structure B3. The fifth upper source/drain contact UC5 may be electrically connected to the third upper source/drain region 263 between the third isolation structure B3 and the third gate structure G3.

The backside source/drain contacts BCr may be electrically connected to the first lower source/drain regions 161, the second lower source/drain regions 162, and the third lower source/drain regions 163. The backside source/drain contacts BCr may penetrate or extend into the substrate 100 and may be electrically connected to the bottoms of the first lower source/drain regions 161, the second lower source/drain regions 162, and the third lower source/drain regions 163.

For example, the backside source/drain contacts BCr may include a second backside source/drain contact BC2 and a sixth backside source/drain contact BC6. The second backside source/drain contact BC2 may be electrically connected to the first lower source/drain region 161 between the first gate structure G1 and the second isolation structure B2. The sixth backside source/drain contact BC6 may be electrically connected to the third lower source/drain region 163 between the third gate structure G3 and the fourth isolation structure B4.

In some embodiments, the second backside source/drain contact BC2 may be electrically connected to the first lower source/drain regions 161 and the first upper source/drain regions 261. For example, between the first gate structure G1 and the second isolation structure B2, a first connecting contact MC1 that penetrates or extends into the intermediate insulating layer 180 and electrically connects the first lower source/drain region 161 and the first upper source/drain region 261 may be formed. The second backside source/drain contact BC2 may be provided as the output node (e.g., Vₒᵤₜ in FIG. 2) of each inverter circuit 10 provided by the first cell region CR1.

In some embodiments, the fourth upper source/drain contact UC4 may be electrically connected to the second lower source/drain regions 162 and the second upper source/drain regions 262. For example, between the second gate structure G2 and the third isolation structure B3, a second connecting contact MC2 that penetrates or extends into the intermediate insulating layer 180 and electrically connects the second lower source/drain region 162 and the second upper source/drain region 262 may be formed. The fourth upper source/drain contact UC4 may be provided as the output node (e.g., Vₒᵤₜ in FIG. 2) of each inverter circuit 10 provided by the second cell region CR2.

In some embodiments, the sixth backside source/drain contact BC6 may be electrically connected to the third lower source/drain regions 163 and the third upper source/drain regions 263. For example, between the third gate structure G3 and the fourth isolation structure B4, a third connecting contact MC3 that penetrates or extends into the intermediate insulating layer 180 and electrically connects the third lower source/drain region 163 and the third upper source/drain region 263 may be formed. The sixth backside source/drain contact BC6 may be provided as the output node (e.g., Vₒᵤₜ in FIG. 2) of each inverter circuit 10 provided by the third cell region CR3.

The front wiring structure FW may be formed on the first surface 100a of the substrate 100. For example, the front wiring structure FW may include a front inter-wiring insulating film 300 that covers or overlaps the interlayer insulating film 280 and front wiring patterns 311, 312, 321, and 322 within the front inter-wiring insulating film 300. The front wiring patterns 311, 312, 321, and 322 may be spaced apart and insulated from one another by the front inter-wiring insulating film 300. The number, shape, and arrangement of the front wiring patterns 311, 312, 321, and 322 are merely example and are not particularly limited.

In some embodiments, the front wiring patterns 311, 312, 321, and 322 may include a first front power supply wire 311, a second front power supply wire 312, a first front connecting wire 321, and a second front connecting wire 322. The first front power supply wire 311, the second front power supply wire 312, the first front connecting wire 321, and the second front connecting wire 322 may each extend in the first direction X.

The first front power supply wire 311 may be commonly connected to the first, second, and third cell regions CR1, CR2, and CR3. The first front power supply wire 311 may be provided as a first power supply line for applying a first power supply voltage (e.g., V_{SS} in FIG. 2) to the first, second, and third cell regions CR1, CR2, and CR3.

In some embodiments, the first front power supply wire 311 may be electrically connected to the first, third, and fifth lower source/drain contacts LC1, LC3, and LC5. For example, parts of the first, third, and fifth lower source/drain contacts LC1, LC3, and LC5 may each overlap with the first front power supply wire 311 in the third direction Z. Each of the first, third, and fifth lower source/drain contacts LC1, LC3, and LC5 may be electrically connected to the first front power supply wire 311 through a first front via pattern 311a extending in the third direction Z.

The second front power supply wire 312 may be spaced apart from the first front power supply wire 311 in the second direction Y. The second front power supply wire 312 may be commonly connected to the first, second, and third cell regions CR1, CR2, and CR3. The second front power supply wire 312 may be provided as a second power supply line for applying a second power supply voltage (e.g., V_{DD} in FIG. 2) different from the first power supply voltage to the first, second, and third cell regions CR1, CR2, and CR3.

In some embodiments, the second front power supply wire 312 may be electrically connected to the first, third, and fifth upper source/drain contacts UC1, UC3, and UC5. For example, parts of the first, third, and fifth upper source/drain contacts UC1, UC3, and UC5 may each overlap with the second front power supply wire 312 in the third direction Z. Each of the first, third, and fifth upper source/drain contacts UC1, UC3, and UC5 may be electrically connected to the second front power supply wire 312 through a second front via pattern 312a extending in the third direction Z.

The first front connecting wire 321 may be interposed between the first and second front power supply wires 311 and 312 in the second direction Y. The first front connecting wire 321 may be electrically connected to the input node (e.g., Vᵢₙ in FIG. 2) of each inverter circuit 10 provided by the first cell region CR1.

For example, part of the first gate structure G1 may overlap with the first front connecting wire 321 in the third direction Z. The first front connecting wire 321 may be electrically connected to the first gate structure G1 through a first front gate contact 321b extending in the third direction Z. The first front gate contact 321b may penetrate or extend into the gate capping film 137 and contact the upper gate electrode 230 of the first gate structure G1. Accordingly, the first front connecting wire 321 may be electrically connected to the first gate structure G1.

The second front connecting wire 322 may be interposed between the first and second front power supply wires 311 and 312 in the second direction Y. The second front connecting wire 322 may electrically connect the output node (e.g., Vₒᵤₜ in FIG. 2) of each inverter circuit 10 provided by the second cell region CR2 and the input node (e.g., Vᵢₙ in FIG. 2) of each inverter circuit 10 provided by the third cell region CR3.

For example, part of the fourth upper source/drain contact UC4 and part of the third gate structure G3 may each overlap with the second front connecting wire 322 in the third direction Z. The second front connecting wire 322 may be electrically connected to the fourth upper source/drain contact UC4 through a third front via pattern 322a extending in the third direction Z. The second front connecting wire 322 may be electrically connected to the third gate structure G3 through a second front gate contact 322b extending in the third direction Z. The second front gate contact 322b may penetrate or extend into the gate capping film 137 and contact the upper gate electrode 230 of the third gate structure G3. Accordingly, the second front connecting wire 322 may electrically connect the fourth upper source/drain contact UC4 and the third gate structure G3.

In some embodiments, the first and second front connecting wires 321 and 322 may be arranged along the first direction X.

The back wiring structure BW may be formed on the second surface 100b of the substrate 100. For example, the back wiring structure BW may include a back inter-wiring insulating film 400 that covers or is on the second surface 100b of the substrate 100, and back wiring patterns 421 and 422 within the back inter-wiring insulating film 400. The back wiring patterns 421 and 422 may be spaced apart and insulated from each other by the back inter-wiring insulating film 400. The number, shape, and arrangement of the back wiring patterns 421 and 422 are merely example and are not particularly limited.

In some embodiments, the back wiring patterns 421 and 422 may include a first back connecting wire 421 and a second back connecting wire 422. The first and second back connecting wires 421 and 422 may each extend in the first direction X.

The first back connecting wire 421 may electrically connect the output node (e.g., Vout in FIG. 2) of the inverter circuit 10 provided by the first cell region CR1 and the input node (e.g., Vin in FIG. 2) of the inverter circuit 10 provided by the second cell region CR2.

For example, part of the second backside source/drain contact BC2 and part of the second gate structure G2 may each overlap with the first back connecting wire 421 in the third direction Z. The first back connecting wire 421 may be electrically connected to the second backside source/drain contact BC2 through a first back via pattern 421a extending in the third direction Z. The first back connecting wire 421 may be electrically connected to the second gate structure G2 through a first back gate contact 421b extending in the third direction Z. The first back gate contact 421b may penetrate or extend into the substrate 100, the base insulating pattern 102, and the gate dielectric film 120 to contact the lower gate electrode 130 of the second gate structure G2. Accordingly, the first back connecting wire 421 may electrically connect the second backside source/drain contact BC2 and the second gate structure G2.

The second back connecting wire 422 may be electrically connected to the output node (e.g., Vₒᵤₜ in FIG. 2) of each inverter circuit 10 provided by the third cell region CR3.

For example, part of the sixth backside source/drain contact BC6 may overlap with the second back connecting wire 422 in the third direction Z. The second back connecting wire 422 may be electrically connected to the sixth backside source/drain contact BC6 through a second back via pattern 422a extending in the third direction Z. Accordingly, the second back connecting wire 422 may be electrically connected to the sixth backside source/drain contact BC6.

In some embodiments, the first and second back connecting wires 421 and 422 may be arranged along the first direction X.

In some embodiments, the first and second cell regions CR1 and CR2 may be alternately arranged along the first direction X. For example, the third cell region CR3 may correspond to the first cell region CR1. The first and second cell regions CR1 and second cell region CR2 may provide a plurality of inverter circuits 10 that are connected in series.

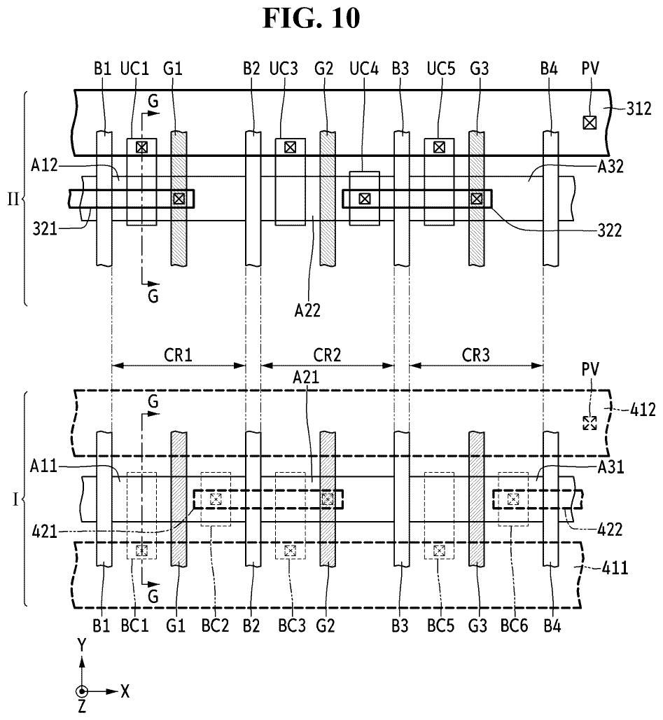

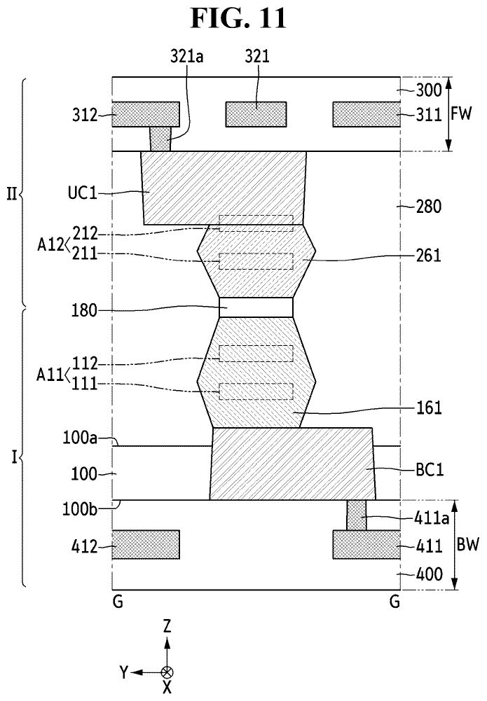

FIG. 10 is an example layout view for explaining a semiconductor device according to some embodiments. FIG. 11 is a schematic cross-sectional view taken along line G-G of FIG. 10. For convenience of explanation, descriptions of content that overlaps with what has been described with reference to FIGS. 1 through 9 will be simplified or omitted.

Referring to FIGS. 1, 2, 10, and 11, in the semiconductor device according to some embodiments, a back wiring structure BW further includes first and second back power supply wires 411 and 412.

First and second back connecting wires 421 and 422 may be interposed between the first and second back power supply wires 411 and 412 in a second direction Y.

The first back power supply wire 411 may be commonly connected to first, second, and third cell regions CR1, CR2, and CR3. The first back power supply wire 411 may be provided as a first power supply line for applying a first power supply voltage (e.g., V_{SS} in FIG. 2) to the first, second, and third cell regions CR1, CR2, and CR3.

In some embodiments, the first back power supply wire 411 may be electrically connected to first, third, and fifth backside source/drain contacts BC1, BC3, and BC5. For example, parts of the first, third, and fifth backside source/drain contacts BC1, BC3, and BC5 may overlap with the first back power supply wire 411 in a third direction Z. The first, third, and fifth backside source/drain contacts BC1, BC3, and BC5 may each be connected to the first back power supply wire 411 through a third back via pattern 411a extending in the third direction Z.

The second back power supply wire 412 may be spaced apart from the first back power supply wire 411 in the second direction Y. The second back power supply wire 412 may be commonly connected to the first, second, and third cell regions CR1, CR2, and CR3. The second back power supply wire 412 may be provided as a second power supply line for applying a second power supply voltage (e.g., V_{DD} in FIG. 2) different from the first power supply voltage to the first, second, and third cell regions CR1, CR2, and CR3.

In some embodiments, the second back power supply wire 412 may be electrically connected to the second front power supply wire 312. For example, the second front power supply wire 312 and the second back power supply wire 412 may overlap with each other in the third direction Z. The second front power supply wire 312 and the second back power supply wire 412 may be electrically connected through a power supply via PV extending in the third direction Z. Accordingly, the second back power supply wire 412 may be electrically connected to first, third, and fifth upper source/drain contacts UC1, UC3, and UC5.

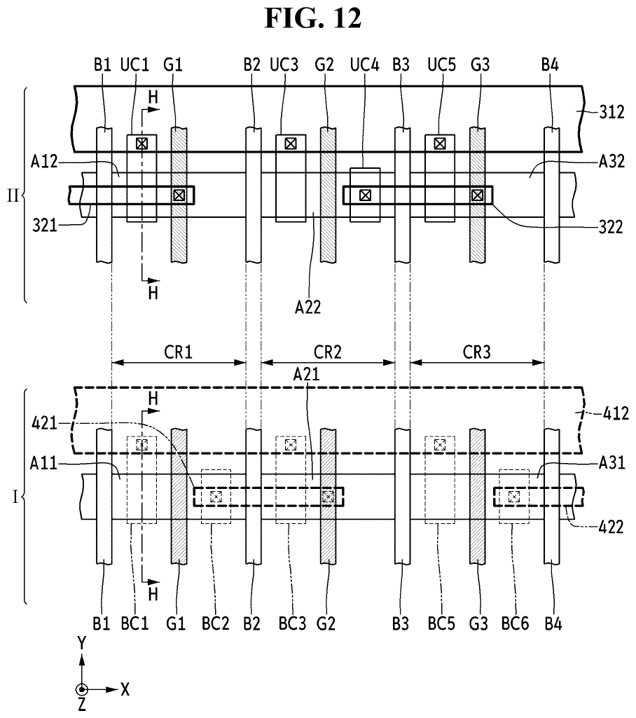

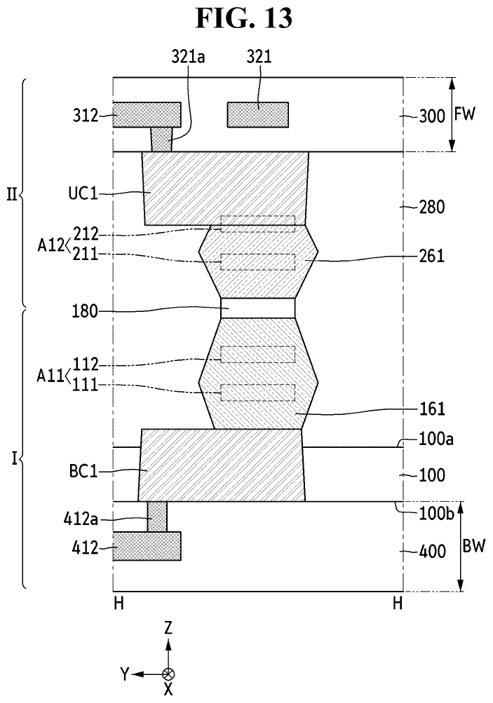

FIG. 12 is an example layout view for explaining a semiconductor device according to some embodiments. FIG. 13 is a schematic cross-sectional view taken along line H-H of FIG. 12. For convenience of explanation, descriptions of content that overlaps with what has been described with reference to FIGS. 1 through 9 will be simplified or omitted.

Referring to FIGS. 1, 2, 12, and 13, in the semiconductor device according to some embodiments, a back wiring structure BW includes a second back power supply wire 412.

The second back power supply wire 412 may be commonly connected to first, second, and third cell regions CR1, CR2, and CR3. The second back power supply wire 412 may be provided as a first power supply line for applying a first power supply voltage (e.g., V_{SS} in FIG. 2) to the first, second, and third cell regions CR1, CR2, and CR3.

In some embodiments, the second back power supply wire 412 may be electrically connected to first, third, and fifth backside source/drain contacts BC1, BC3, and BC5. For example, parts of the first, third, and fifth backside source/drain contacts BC1, BC3, and BC5 may overlap with the second back power supply wire 412 in a third direction Z. The first, third, and fifth backside source/drain contacts BC1, BC3, and BC5 may each be connected to the second back power supply wire 412 through a fourth back via pattern 412a extending in the third direction Z.

In some embodiments, the second back power supply wire 412 may overlap with a second front power supply wire 312 in the third direction Z.

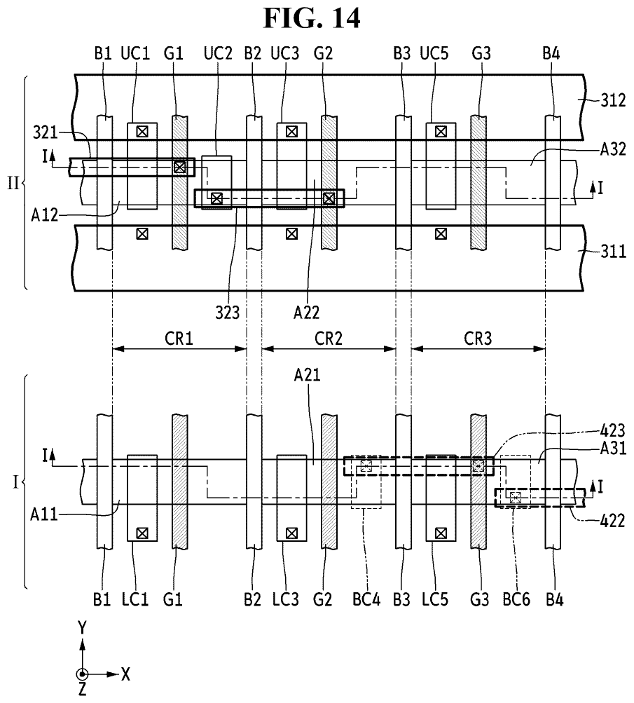

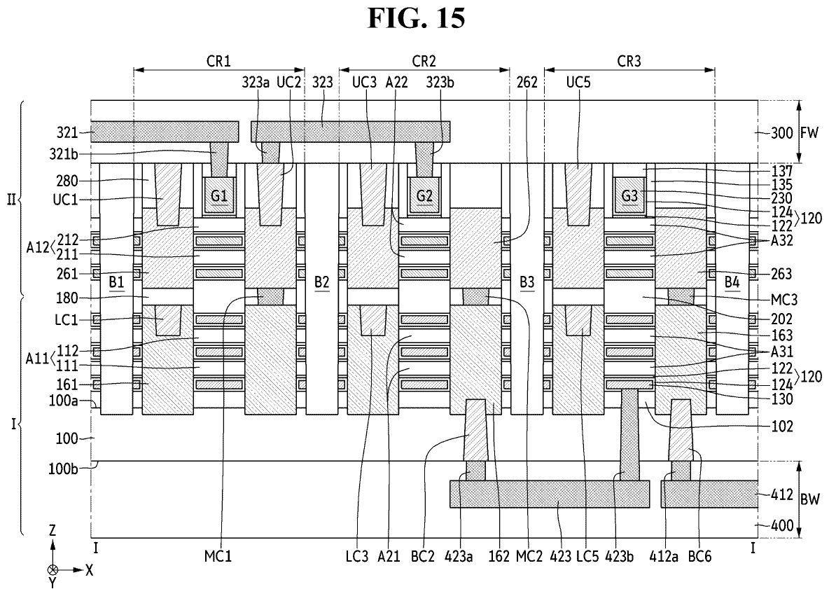

FIG. 14 is an example layout view for explaining a semiconductor device according to some embodiments. FIG. 15 is a schematic cross-sectional view taken along line I-I of FIG. 14. For convenience of explanation, descriptions of content that overlaps with what has been described with reference to FIGS. 1 through 13 will be simplified or omitted.

Referring to FIGS. 1, 2, 14, and 15, in the semiconductor device according to some embodiments, a front wiring structure FW includes a third front connecting wire 323, and a back wiring structure BW includes a third back connecting wire 423.

The third front connecting wire 323 may electrically connect the output node (e.g., Vₒᵤₜ in FIG. 2) of each inverter circuit 10 provided by a first cell region CR1 and the input node (e.g., Vᵢₙ in FIG. 2) of each inverter circuit 10 provided by a second cell region CR2.

For example, parts of a second upper source/drain contact UC2 and a second gate structure G2 may each overlap with the third front connecting wire 323 in a third direction Z. The third front connecting wire 323 may be electrically connected to the second upper source/drain contact UC2 through a fourth front via pattern 323a extending in the third direction Z. The third front connecting wire 323 may be electrically connected to the second gate structure G2 through a third front gate contact 323b extending in the third direction Z. The third front gate contact 323b may penetrate or extend into a gate capping film 137 and contact an upper gate electrode 230 of the second gate structure G2. Accordingly, the third front connecting wire 323 may electrically connect the second upper source/drain contact UC2 and the second gate structure G2.

The third front connecting wire 323 is illustrated as not being arranged along a first direction X with the first front connecting wire 321, but the present disclosure is not limited thereto. In some embodiments, the third front connecting wire 323 may be arranged along the first direction X with the first front connecting wire 321 as long as it is separated from the first front connecting wire 321.

The third back connecting wire 423 may connect the output node (e.g., Vₒᵤₜ in FIG. 2) of each inverter circuit 10 provided by the second cell region CR2 and the input node (e.g., Vᵢₙ in FIG. 2) of each inverter circuit 10 provided by a third cell region CR3.

For example, parts of a fourth backside source/drain contact BC4 and a third gate structure G3 may each overlap with the third back connecting wire 423 in the third direction Z. The third back connecting wire 423 may be electrically connected to the fourth backside source/drain contact BC4 through a fifth back via pattern 432a extending in the third direction Z. The third back connecting wire 423 may be electrically connected to the third gate structure G3 through a second back gate contact 423b extending in the third direction Z. The second back gate contact 423b may penetrate or extend into a substrate 100, a base insulating pattern 102, and a gate dielectric film 120 to contact a lower gate electrode 130 of the third gate structure G3. Accordingly, the third back connecting wire 423 may electrically connect the fourth backside source/drain contact BC4 and the third gate structure G3.

The third back connecting wire 423 is illustrated as not being arranged along the first direction X with the second back connecting wire 422, but the present disclosure is not limited thereto. In some embodiments, the third back connecting wire 423 may be arranged along the first direction X with the second back connecting wire 422 as long as it is separated from the second back connecting wire 422.

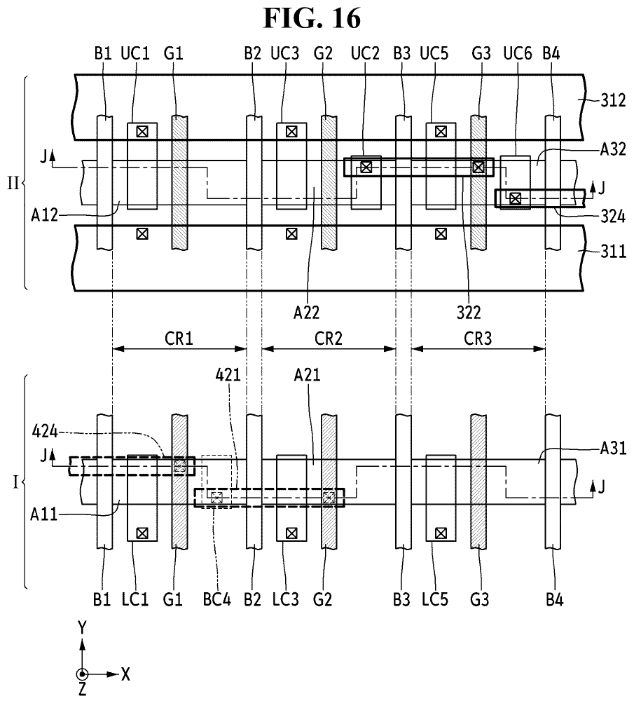

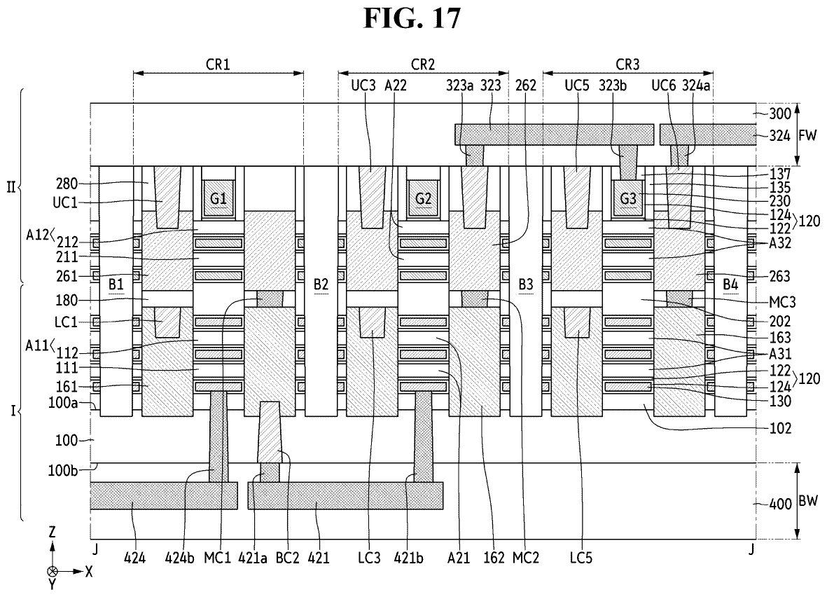

FIG. 16 is an example layout view for explaining a semiconductor device according to some embodiments. FIG. 17 is a schematic cross-sectional view taken along line J-J of FIG. 16. For convenience of explanation, descriptions of content that overlap with what has been described with reference to FIGS. 1 through 13 will be simplified or omitted.

Referring to FIGS. 1, 2, 16, and 17, in the semiconductor device according to some embodiments, a front wiring structure FW includes a fourth front connecting wire 324, and a back wiring structure BW includes a fourth back connecting wire 424.

The fourth front connecting wire 324 may be electrically connected to the output node (e.g., Vₒᵤₜ in FIG. 2) of each inverter circuit 10 provided by a third cell region CR3.

For example, part of a sixth upper source/drain contact UC6 may overlap with the fourth front connecting wire 324 in a third direction Z. The fourth front connecting wire 324 may be connected to the sixth upper source/drain contact UC6 through a fifth front via pattern 324a extending in the third direction Z. Accordingly, the fourth front connecting wire 324 may be electrically connected to the sixth upper source/drain contact UC6.

The fourth front connecting wire 324 is illustrated as not being arranged along the first direction X with the second front connecting wire 322, but the present disclosure is not limited thereto. In some embodiments, the fourth front connecting wire 324 may be arranged along the first direction X with the second front connecting wire 322 as long as it is separated from the second front connecting wire 322.

The fourth back connecting wire 424 may be electrically connected to the input node (e.g., Vᵢₙ in FIG. 2) of each inverter circuit 10 provided by a first cell region CR1.

For example, part of a first gate structure G1 may overlap with the fourth back connecting wire 424 in the third direction Z. The fourth back connecting wire 424 may be connected to the first gate structure G1 through a third back gate contact 424b extending in the third direction Z. The third back gate contact 424b may penetrate or extend into a substrate 100, a base insulating pattern 102, and a gate dielectric film 120 to contact a lower gate electrode 130 of the first gate structure G1. Accordingly, the fourth back connecting wire 424 may electrically connect the first gate structure G1.

The fourth back connecting wire 424 is illustrated as not being arranged along the first direction X with the first back connecting wire 421, but the present disclosure is not limited thereto. In some embodiments, the fourth back connecting wire 424 may be arranged along the first direction X with the first back connecting wire 421 as long as it is separated from the first back connecting wire 421.

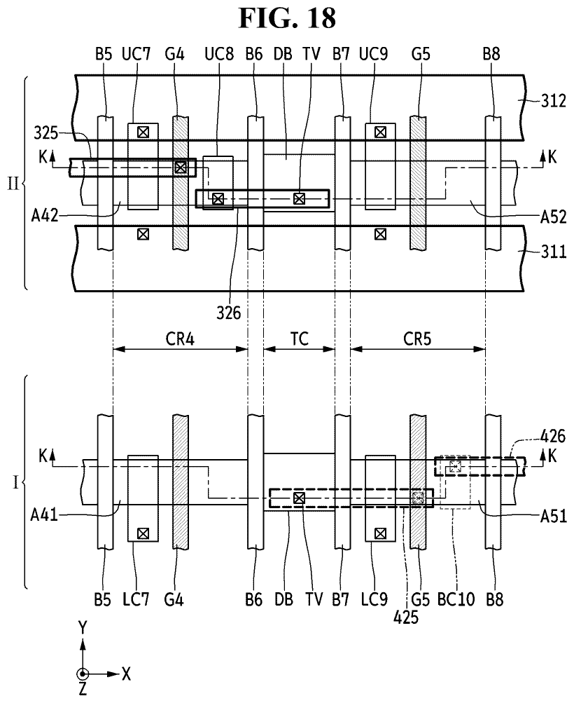

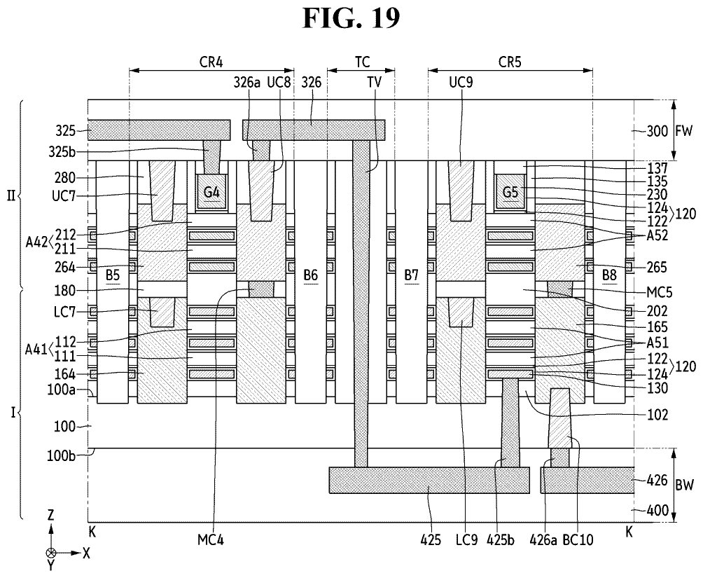

FIG. 18 is an example layout view for explaining a semiconductor device according to some embodiments. FIG. 19 is a schematic cross-sectional view taken along line K-K of FIG. 18. For convenience of explanation, descriptions of content that overlaps with what has been described with reference to FIGS. 1 through 17 will be simplified or omitted.

Referring to FIGS. 1, 2, 18, and 19, the semiconductor device according to some embodiments includes a fourth cell region CR4, a tap cell region TC, and a fifth cell region CR5.

The fourth cell region CR4, the tap cell region TC, and the fifth cell region CR5 may be sequentially arranged along a first direction X. The tap cell region TC may be interposed between the fourth cell region CR4 and the fifth cell region CR5 in the first direction X.

The fourth and fifth cell regions CR4 and CR5 may each provide each inverter circuit 10 of FIGS. 1 and 2 on the substrate 100. The fourth cell region CR4 and the fifth cell region CR5 may be connected in series. For example, the output signal of the fourth cell region CR4 may be provided as an input signal to the fifth cell region CR5.

The semiconductor device according to some embodiments may include a fourth lower active pattern A41, a fifth lower active pattern A51, a fourth upper active pattern A42, a fifth upper active pattern A52, a fourth gate structure G4, a fifth gate structure G5, fifth through eighth isolation structures B5 through B8, a fourth lower source/drain region 164, a fifth lower source/drain region 165, a fourth upper source/drain region 264, a fifth upper source/drain region 265, and a through via TV.

The fourth lower active pattern A41 and the fourth upper active pattern A42 may be sequentially stacked on the first surface 100a of the fourth cell region CR4. The fourth gate structure G4 may intersect the fourth lower active pattern A41 and the fourth upper active pattern A42. The fourth lower source/drain region 164 may be formed in the fourth lower active pattern A41 on the side of the fourth gate structure G4. The fourth upper source/drain region 264 may be formed in the fourth upper active pattern A42 on the side of the fourth gate structure G4.

The fifth lower active pattern A51 and the fifth upper active pattern A52 may be sequentially stacked on the first surface 100a of the fifth cell region CR5. The fifth gate structure G5 may intersect the fifth lower active pattern A51 and the fifth upper active pattern A52. The fifth lower source/drain region 165 may be formed in the fifth lower active pattern A51 on the side of the fifth gate structure G5. The fifth upper source/drain region 265 may be formed in the fifth upper active pattern A52 on the side of the fifth gate structure G5.

A first front power supply wire 311 may be commonly connected to the fourth and fifth cell regions CR4 and CR5. The first front power supply wire 311 may be provided as a first power supply line for applying a first power supply voltage (e.g., V_{SS} in FIG. 2) to the fourth and fifth cell regions CR4 and CR5.

For example, lower source/drain contacts LCp may include a seventh lower source/drain contact LC7 and a ninth lower source/drain contact LC9. The seventh lower source/drain contact LC7 may be electrically connected to the fourth lower source/drain region 164 between the fifth isolation structure B5 and the fourth gate structure G4. The ninth lower source/drain contact LC9 may be electrically connected to the fifth lower source/drain region 165 between the seventh isolation structure B7 and the fifth gate structure G5. The first front power supply wire 311 may be electrically connected to the seventh and ninth lower source/drain contacts LC7 and LC9.

The second front power supply wire 312 may be commonly connected to the fourth and fifth cell regions CR4 and CR5. The second front power supply wire 312 may be provided as a second power supply line for applying a second power supply voltage (e.g., V_{DD} in FIG. 2) different from the first power supply voltage to the fourth and fifth cell regions CR4 and CR5.

For example, upper source/drain contacts UCq may include a seventh upper source/drain contact UC7 and a ninth upper source/drain contact UC9. The seventh upper source/drain contact UC7 may be electrically connected to the fourth upper source/drain region 264 between the fifth isolation structure B5 and the fourth gate structure G4. The ninth upper source/drain contact UC9 may be electrically connected to the fifth upper source/drain region 265 between the seventh isolation structure B7 and the fifth gate structure G5. The second front power supply wire 312 may be electrically connected to the seventh and ninth upper source/drain contacts UC7 and UC9.

In some embodiments, a front wiring structure FW may include a fifth front connecting wire 325 and a sixth front connecting wire 326. The fifth and sixth front connecting wires 325 and 326 may each extend in the first direction X.

The fifth front connecting wire 325 may be electrically connected to the input node (e.g., Vᵢₙ in FIG. 2) of each inverter circuit 10 provided by the fourth cell region CR4.

For example, part of the fourth gate structure G4 may overlap with the fifth front connecting wire 325 in a third direction Z. The fifth front connecting wire 325 may be electrically connected to the fourth gate structure G4 through a fourth front gate contact 325b extending in the third direction Z. The fourth front gate contact 325b may penetrate or extend into a gate capping film 137 and contact an upper gate electrode 230 of the fourth gate structure G4. Accordingly, the fifth front connecting wire 325 may be electrically connected to the fourth gate structure G4.

The sixth front connecting wire 326 may be connected to the output node (e.g., Vₒᵤₜ in FIG. 2) of each inverter circuit 10 provided by the fourth cell region CR4.

For example, the upper source/drain contacts UCq may include an eighth upper source/drain contact UC8. The eighth upper source/drain contact UC8 may be electrically connected to the fourth upper source/drain region 264 between the fourth gate structure G4 and the sixth isolation structure B6. The eighth upper source/drain contact UC8 may be electrically connected to the fourth lower source/drain region 164 and the fourth upper source/drain region 264. For example, between the fourth gate structure G4 and the sixth isolation structure B6, a fourth connecting contact MC4 that penetrates or extends into an intermediate insulating layer 180 and electrically connects the fourth lower source/drain region 164 and the fourth upper source/drain region 264 may be formed. The eighth upper source/drain contact UC8 may be provided as the output node (e.g., Vₒᵤₜ in FIG. 2) of each inverter circuit 10 provided by the fourth cell region CR4.

Part of the eighth upper source/drain contact UC8 may overlap with the sixth front connecting wire 326 in the third direction Z. The sixth front connecting wire 326 may be electrically connected to the eighth upper source/drain contact UC8 through a sixth front via pattern 326a extending in the third direction Z. Accordingly, the sixth front connecting wire 326 may be electrically connected to the eighth upper source/drain contact UC8.

In some embodiments, a back wiring structure BW may include a fifth back connecting wire 425 and a sixth back connecting wire 426. The fifth and sixth back connecting wires 425 and 426 may each extend in the first direction X.

The fifth back connecting wire 425 may be electrically connected to the input node (e.g., Vᵢₙ in FIG. 2) of each inverter circuit 10 provided by the fifth cell region CR5.

For example, part of the fifth gate structure G5 may overlap with the fifth back connecting wire 425 in the third direction Z. The fifth back connecting wire 425 may be electrically connected to the fifth gate structure G5 through a fifth back gate contact 425b extending in the third direction Z. The fifth back gate contact 425b may penetrate or extend into a substrate 100, a base insulating pattern 102, and a gate dielectric film 120 to contact a lower gate electrode 130 of the fifth gate structure G5. Accordingly, the fifth back connecting wire 425 may be electrically connected to the fifth gate structure G5.

The sixth back connecting wire 426 may be electrically connected to the output node (e.g., Vₒᵤₜ in FIG. 2) of each inverter circuit 10 provided by the fifth cell region CR5.

For example, backside source/drain contacts BCr may include a tenth backside source/drain contact BC10. The tenth backside source/drain contact BC10 may be electrically connected to the fifth lower source/drain region 165 between the fifth gate structure G5 and the eighth isolation structure B8. The tenth backside source/drain contact BC10 may be electrically connected to the fifth lower source/drain region 165 and the fifth upper source/drain region 265. For example, between the fifth gate structure G5 and the eighth isolation structure B8, a fifth connecting contact MC5 that penetrates or extends into the intermediate insulating layer 180 and connects the fifth lower source/drain region 165 and the fifth upper source/drain region 265 may be formed. The tenth backside source/drain contact BC10 may be provided as the output node (e.g., Vₒᵤₜ in FIG. 2) of each inverter circuit 10 provided by the fifth cell region CR5.

Part of the tenth backside source/drain contact BC10 may overlap with the sixth back connecting wire 426 in the third direction Z. The sixth back connecting wire 426 may be electrically connected to the tenth backside source/drain contact BC10 through a sixth back via pattern 426a extending in the third direction Z. Accordingly, the sixth back connecting wire 426 may be electrically connected to the tenth backside source/drain contact BC10.

The through via TV may penetrate or extend into the substrate 100 of the tap cell region TC. For example, an insulating structure DB may be formed between the sixth and seventh isolation structures B6 and B7 on a first surface 100a of the substrate 100. The through via TV may extend in the third direction Z and penetrate or extend into the substrate 100 and the insulating structure DB.

The through via TV may electrically connect the output node (e.g., Vₒᵤₜ in FIG. 2) of each inverter circuit 10 provided by the fourth cell region CR4 to the input node (e.g., Vᵢₙ in FIG. 2) of each inverter circuit 10 provided by the fifth cell region CR5.

For example, part of the sixth front connecting wire 326 and part of the fifth back connecting wire 425 may each overlap with the through via TV in the third direction Z. The through via TV may extend in the third direction Z to electrically connect the sixth front connecting wire 326 and the fifth back connecting wire 425. Accordingly, the eighth upper source/drain contact UC8 and the fifth gate structure G5 may be electrically connected.

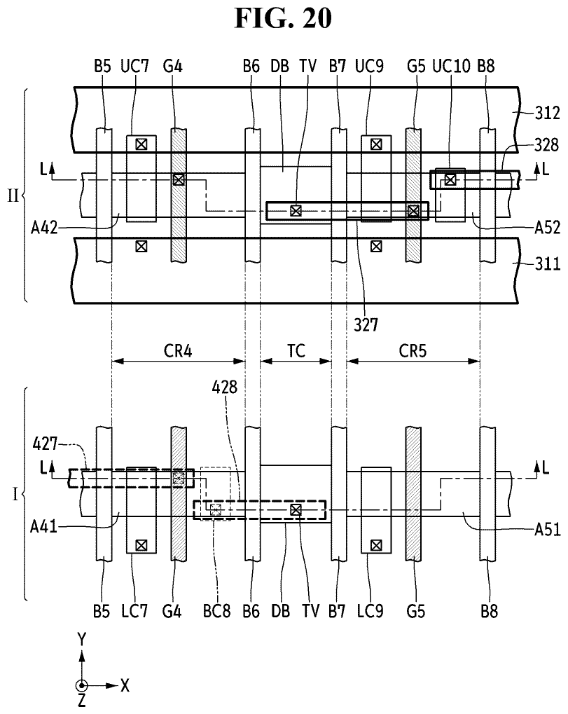

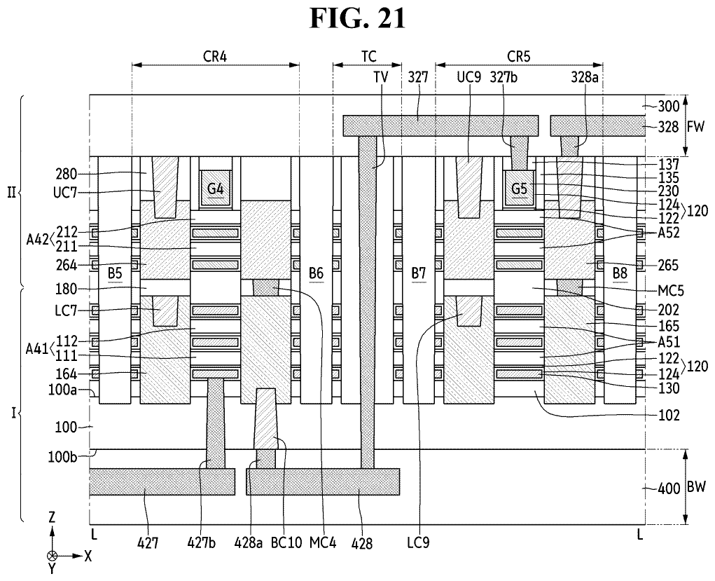

FIG. 20 is an example layout view for explaining a semiconductor device according to some embodiments. FIG. 21 is a schematic cross-sectional view taken along line L-L of FIG. 20. For convenience of explanation, descriptions of content that overlaps with what has been described with reference to FIGS. 1 through 19 will be simplified or omitted.

Referring to FIGS. 1, 2, 20, and 21, in the semiconductor device according to some embodiments, a front wiring structure FW includes a seventh front connecting wire 327 and an eighth front connecting wire 328, and a back wiring structure BW includes a seventh back connecting wire 427 and an eighth back connecting wire 428.

The seventh front connecting wire 327 may be connected to the input node (e.g., Vᵢₙ in FIG. 2) of each inverter circuit 10 provided by a fifth cell region CR5.

For example, part of a fifth gate structure G5 may overlap with the seventh front connecting wire 327 in a third direction Z. The seventh front connecting wire 327 may be connected to the fifth gate structure G5 through a fifth front gate contact 327b extending in the third direction Z. The fifth front gate contact 327b may penetrate or extend into a gate capping film 137 to contact an upper gate electrode 230 of the fifth gate structure G5. Accordingly, the seventh front connecting wire 327 may be electrically connected to the fifth gate structure G5.

The eighth front connecting wire 328 may be electrically connected to the output node (e.g., Vₒᵤₜ in FIG. 2) of each inverter circuit 10 provided by the fifth cell region CR5.

For example, upper source/drain contacts UCq may include a tenth upper source/drain contact UC10. The tenth upper source/drain contact UC10 may be electrically connected to a fifth upper source/drain region 265 between the fifth gate structure G5 and an eighth isolation structure B8. The tenth upper source/drain contact UC10 may be electrically connected to a fifth lower source/drain region 165 and the fifth upper source/drain region 265. For example, between the fifth gate structure G5 and the eighth isolation structure B8, a fifth connecting contact MC5 that penetrates or extends into an intermediate insulating layer 180 and electrically connects the fifth lower source/drain region 165 and the fifth upper source/drain region 265 may be formed. The tenth upper source/drain contact UC10 may be provided as the output node (e.g., Vₒᵤₜ in FIG. 2) of each inverter circuit 10 provided by the fifth cell region CR5.

Part of the tenth upper source/drain contact UC10 may overlap with the eighth front connecting wire 328 in the third direction Z. The eighth front connecting wire 328 may be electrically connected to the tenth upper source/drain contact UC10 through a seventh front via pattern 328a extending in the third direction Z. Accordingly, the eighth front connecting wire 328 may be electrically connected to the tenth upper source/drain contact UC10.

The seventh back connecting wire 427 may be electrically connected to the input node (e.g., Vᵢₙ in FIG. 2) of each inverter circuit 10 provided by a fourth cell region CR4.

For example, part of a fourth gate structure G4 may overlap with the seventh back connecting wire 427 in the third direction Z. The seventh back connecting wire 427 may be electrically connected to the fourth gate structure G4 through a fourth back gate contact 427b extending in the third direction Z. The fourth back gate contact 427b may penetrate or extend into a substrate 100, a base insulating pattern 102, and a gate dielectric film 120 to contact a lower gate electrode 130 of the fourth gate structure G4. Accordingly, the seventh back connecting wire 427 may be electrically connected to the fourth gate structure G4.

The eighth back connecting wire 428 may be electrically connected to the output node (e.g., Vₒᵤₜ in FIG. 2) of each inverter circuit 10 provided by the fourth cell region CR4.

For example, backside source/drain contacts BCr may include an eighth backside source/drain contact BC8. The eighth backside source/drain contact BC8 may be electrically connected to a fourth lower source/drain region 164 between the fourth gate structure G4 and the sixth isolation structure B6. The eighth backside source/drain contact BC8 may be electrically connected to the fourth lower source/drain region 164 and the fourth upper source/drain region 264. For example, between the fourth gate structure G4 and the sixth isolation structure B6, a fourth connecting contact MC4 that penetrates or extends into the intermediate insulating layer 180 and electrically connects the fourth lower source/drain region 164 and the fourth upper source/drain region 264 may be formed. The eighth backside source/drain contact BC8 may be provided as the output node (e.g., Vₒᵤₜ in FIG. 2) of each inverter circuit 10 provided by the fourth cell region CR4.

Part of the eighth backside source/drain contact BC8 may overlap with the eighth back connecting wire 428 in the third direction Z. The eighth back connecting wire 428 may be electrically connected to the eighth backside source/drain contact BC8 through a sixth back via pattern 428a extending in the third direction Z. Accordingly, the eighth back connecting wire 428 may be electrically connected to the eighth backside source/drain contact BC8.

A through via TV may electrically connect the output node (e.g., Vₒᵤₜ in FIG. 2) of each inverter circuit 10 provided by the fourth cell region CR4 to the input node (e.g., Vᵢₙ in FIG. 2) of each inverter circuit 10 provided by the fifth cell region CR5.

For example, part of the eighth back connecting wire 428 and part of the seventh front connecting wire 327 may overlap with the through via TV in the third direction Z. The through via TV may extend in the third direction Z to electrically connect the eighth back connecting wire 428 and the seventh front connecting wire 327. Accordingly, the eighth backside source/drain contact BC8 and the fifth gate structure G5 may be electrically connected.

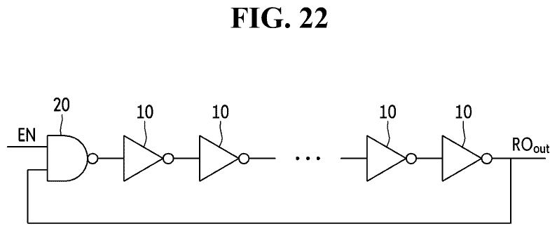

FIG. 22 is an example circuit diagram for explaining a semiconductor device according to some embodiments. For convenience of explanation, descriptions of content that overlaps with what has been described with reference to FIGS. 1 through 21 will be simplified or omitted.

Referring to FIG. 22, the semiconductor device according to some embodiments includes a plurality of inverter circuits 10 that are connected in series to form a closed-loop circuit.

In some embodiments, the semiconductor device according to some embodiments may include an odd number of inverter circuits 10 connected in series to form a closed-loop circuit. These odd number of inverter circuits 10 may be provided as ring oscillator circuits, where an output signal ROₒᵤₜ oscillates.

In some embodiments, a NAND gate circuit 20 may be connected to the inverter circuits 10, provided as ring oscillators. The NAND gate circuit 20 may receive the output signal ROₒᵤₜ of each of the inverter circuits 10 and an external input signal EN as input signals. The output signal of the NAND gate circuit 20 may be provided as an input signal to each of the inverter circuits 10.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor device comprising:
a substrate including first and second surfaces that are opposite to each other;
a first lower active pattern extending in a first direction on the first surface of the substrate;
a first upper active pattern on the first lower active pattern and extending in the first direction;
a first gate structure, extending in a second direction which intersects the first direction, on the first lower active pattern and on the first upper active pattern;
a second lower active pattern extending in the first direction on the substrate and spaced apart from the first lower active pattern in the first direction;
a second upper active pattern on the second lower active pattern, extending in the first direction, and spaced apart from the first upper active pattern in the first direction;
a second gate structure extending in the second direction on the second lower active pattern and on the second upper active pattern;
a first source/drain contact electrically connected to a first lower source/drain region of the first lower active pattern;
a first upper source/drain region of the first upper active pattern on the first source/drain contact; and
a first back connecting wire extending in the first direction and electrically connecting the first source/drain contact and the second gate structure.

2. The semiconductor device of claim 1, wherein the first source/drain contact extends into the substrate and electrically connects to the first lower source/drain region.

3. The semiconductor device of claim 2, further comprising:
a back gate contact that extends into the substrate and electrically connects to the second gate structure and the first back connecting wire.

4. The semiconductor device of claim 1, further comprising:
a second source/drain contact electrically connected to the first lower source/drain region, wherein the first gate structure is between the first source/drain contact and the second source/drain contact;
a third source/drain contact electrically connected to the first upper source/drain region, wherein the first gate structure is between the first source/drain contact and the third source/drain contact;
a fourth source/drain contact electrically connected to a second lower source/drain region of the second lower active pattern;
a fifth source/drain contact electrically connected to a second upper source/drain region of the second upper active pattern;
a first power supply wire extending in the first direction and electrically connected to both the second and fourth source/drain contacts; and
a second power supply wire extending in the first direction and electrically connected to both the third and fifth source/drain contacts.

5. The semiconductor device of claim 4, wherein the first and second power supply wires are on the first surface of the substrate.

6. The semiconductor device of claim 4, wherein at least one of the first and second power supply wires is on the second surface of the substrate.

7. The semiconductor device of claim 1, further comprising:
a third lower active pattern extending in the first direction on the first surface of the substrate and spaced apart from the second lower active pattern in the first direction;
a third upper active pattern on the third lower active pattern, extending in the first direction, and spaced apart from the second upper active pattern in the first direction;
a third gate structure extending in the second direction on the third lower active pattern and the third upper active pattern;
a second source/drain contact electrically connected to a second lower source/drain region of the second lower active pattern and a second upper source/drain region of the second upper active pattern; and
a first front connecting wire extending in the first direction on the first surface of the substrate and electrically connecting the second source/drain contact and the third gate structure.

8. The semiconductor device of claim 7, further comprising:
a second front connecting wire extending in the first direction on the first surface of the substrate and electrically connected to the first gate structure.

9. The semiconductor device of claim 7, further comprising:
a third source/drain contact electrically connected to a third lower source/drain region of the third lower active pattern and a third upper source/drain region of the third upper active pattern; and
a second back connecting wire extending in the first direction on the second surface of the substrate and electrically connected to the third source/drain contact.

10. The semiconductor device of claim 1, further comprising:
a through via that extends into the substrate; and
a front connecting wire extending in the first direction on the first surface of the substrate and electrically connecting the first source/drain contact and the through via,
wherein the first back connecting wire electrically connects the through via and the second gate structure.

11. The semiconductor device of claim 1, further comprising:
a through via that extends into the substrate; and
a front connecting wire extending in the first direction on the first surface of the substrate and electrically connecting the through via and the second gate structure,
wherein the first back connecting wire electrically connects the first source/drain contact and the through via.

12. The semiconductor device of claim 1, further comprising:
an isolation structure extending in the second direction between the first and second gate structures,
wherein the first lower source/drain region is electrically isolated from a second lower source/drain region of the second lower active pattern by the isolation structure, and
wherein the first upper source/drain region is electrically isolated from a second upper source/drain region of the second upper active pattern by the isolation structure.

13. A semiconductor device comprising:
a substrate including a first surface and a second surface that are opposite to each other;
a plurality of cell regions electrically connected in series on the substrate, each of the cell regions comprising an inverter circuit;
a front wiring structure on the first surface of the substrate; and
a back wiring structure on the second surface of the substrate,
wherein the cell regions include first and second cell regions that are alternately arranged,
wherein the first cell region comprises:
a first lower active pattern on the first surface of the substrate and extending in a first direction;
a first upper active pattern on the first lower active pattern and extending in the first direction;
a first gate structure, extending in a second direction intersecting the first direction, on the first lower active pattern and on the first upper active pattern; and
a first source/drain contact electrically connected to a first lower source/drain region of the first lower active pattern and a first upper source/drain region of the first upper active pattern,
wherein the second cell region comprises:
a second lower active pattern on the first surface of the substrate and extending in the first direction;
a second upper active pattern on the second lower active pattern and extending in the first direction;
a second gate structure extending in the second direction on the second lower active pattern and the second upper active pattern; and
a second source/drain contact electrically connected to a second lower source/drain region of the second lower active pattern and a second upper source/drain region of the second upper active pattern,
wherein the first gate structure and the second source/drain contact are electrically connected to the front wiring structure, and
wherein the first source/drain contact and the second gate structure are electrically connected to the back wiring structure.

14. The semiconductor device of claim 13, wherein the front wiring structure includes a first front connecting wire electrically connected to the first gate structure, and a second front connecting wire spaced apart from the first front connecting wire and electrically connected to the second source/drain contact.

15. The semiconductor device of claim 13, wherein the back wiring structure includes a back connecting wire electrically connecting the first source/drain contact and the second gate structure.

16. The semiconductor device of claim 13, wherein the cell regions include an odd number of cell regions electrically connected in series to form a closed-loop circuit.

17. A semiconductor device comprising:
a substrate including a first surface and a second surface that are opposite to each other;
an odd number of cell regions electrically connected in series on the substrate to form a closed-loop circuit, wherein each of the cell regions comprise an inverter circuit; and
a back connecting wire on the second surface of the substrate,
wherein each of the cell regions comprises:
a lower active pattern on the first surface of the substrate;
an upper active pattern on the lower active pattern;
a gate structure intersecting the lower active pattern and the upper active pattern; and
a source/drain contact electrically connected to a lower source/drain region of the lower active pattern and an upper source/drain region of the upper active pattern, and
wherein the back connecting wire is electrically connected to the source/drain contact or a gate electrode of at least one of the cell regions.

18. The semiconductor device of claim 17, wherein the cell regions include first and second cell regions that are adjacent to each other, and
wherein the back connecting wire electrically connects the source/drain contact of the first cell region and the gate structure of the second cell region.

19. The semiconductor device of claim 18, further comprising:
a front connecting wire electrically connected to the gate structure of the first cell region, on the first surface of the substrate.

20. The semiconductor device of claim 18, further comprising:
a front connecting wire electrically connected to the source/drain contact of the second cell region, on the first surface of the substrate.
